(19) United States
(12) Patent Application Publication
(10) Pub. No.: US 2025/0031338 A1
(43) Pub. Date: Jan. 23, 2025

(54) MOBILE SYNCHRONOUS CONDENSER SYSTEM

(71) Applicant: Vince Sigal, Santa Rosa, CA (US)

(72) Inventor: Vince Sigal, Santa Rosa, CA (US)

(21) Appl. No.: 18/780,003

(22) Filed: Jul. 22, 2024

Related U.S. Application Data
(60) Provisional application No. 63/514,762, filed on Jul. 20, 2023.

(51) Int. Cl. H05K 7/20; H02J 3/18; H02J 3/24

(52) U.S. Cl. CPC H05K 7/20181; H02J 3/1885; H02J 3/241; H05K 7/20172

(57) ABSTRACT

A mobile synchronous condenser system and method uses a container, where a synchronous condenser unit is positioned within the container. A power panel is attached to the container. The synchronous condenser unit is electrically connected to the power panel via at least one cable, where the power panel includes at least one connector to connect to an electrical power network using at least one external cable.

### CROSS-REFERENCE TO RELATED APPLICATIONS

This application is entitled to the benefit of U.S. Provisional Patent Application Ser. No. 63/514,762, filed on Jul. 20, 2023, which is incorporated herein by reference.

### BACKGROUND

Synchronous condensers are specialized devices used in electrical power systems to manage voltage stability and improve power quality. Synchronous condensers operate as synchronous machines similar to generators but without the mechanical load connection, functioning solely to provide or absorb reactive power as needed. By injecting or absorbing reactive power, synchronous condensers serve as stabilizers for the grid, assisting in the maintenance of both grid frequency and voltage. The inertia provided by rotating generators in power stations acts as a buffer for frequency response, allowing thermal generation to adjust rapidly to match grid demand.

Thus, synchronous condensers play a crucial role in delivering and absorbing reactive power, which supports grid voltage stability essential for the effective distribution of active power. Even minor voltage deviations can jeopardize grid integrity and lead to power outages, underscoring the critical importance of maintaining optimal levels of reactive power, akin to ensuring appropriate pressure in a fire hose.

The use of synchronous condensers as part of electrical grid has been largely phased out due to the evolution of power electronics. However, power electronics struggle to provide equivalent support with all the new renewables, such as solar, wind and batteries, being introduced since the power electronics cannot provide the short circuit support (voltage) and inertia support (frequency) in the same way as the synchronous condensers. Thus, synchronous condensers are particularly valuable in modern grids with high penetration of renewable energy sources, where their ability to quickly adjust reactive power output helps mitigate fluctuations caused by intermittent renewable generation.

One of the challenges associated with traditional synchronous condensers is their requirement for installation at a designated facility, such as a substation. This necessitates the assembly and interconnection of numerous components, usually within a dedicated building structure. Once installed, traditional synchronous condensers are generally immobile and cannot be easily relocated to alternative facilities due to the permanent nature of their installation process.

### SUMMARY

A mobile synchronous condenser system and method uses a container, where a synchronous condenser unit is positioned within the container. A power panel is attached to the container. The synchronous condenser unit is electrically connected to the power panel via at least one cable, where the power panel includes at least one connector to connect to an electrical power network using at least one external cable.

A mobile synchronous condenser system in accordance with an embodiment of the invention comprises a container, a synchronous condenser unit attached to the container such that the synchronous condenser unit is positioned within the container, and a power panel attached to the container, wherein the synchronous condenser unit is electrically connected to the power panel via at least one cable, wherein the power panel includes at least one connector to connect to an electrical power network using at least one external cable.

A mobile synchronous condenser system in accordance with another embodiment of the invention comprises a shipping container, a synchronous condenser unit attached to the shipping container such that the synchronous condenser unit is positioned within the shipping container, a power panel attached to the shipping container, wherein the synchronous condenser unit is electrically connected to the power panel via at least one cable, wherein the power panel includes at least one connector to connect to an electrical power network using at least one external cable, and a temperature control system attached to the shipping container to control a temperature of an operating environment within the shipping container for the synchronous condenser unit.

A method in accordance with an embodiment of the invention comprises placing a synchronous condense unit in a container, attaching the synchronous condense unit to the container, installing a temperature control system in the container to control the temperature of an operating environment within the container for the synchronous condenser unit, and connecting at least one cable between the synchronous condense unit to a power panel on the container for connection to an electric power network.

These and other aspects in accordance with embodiments will become apparent from the following detailed description, taken in conjunction with the accompanying drawings, illustrated by way of example of the principles of the embodiments.

### BRIEF DESCRIPTION OF THE DRAWINGS

FIG. 1 is a top perspective view of a mobile synchronous condenser system, which the roof of a container of the system removed, in accordance with an embodiment of the invention.

FIG. 2 is a diagram of a synchronous condenser unit of the mobile synchronous condenser system in accordance with an embodiment of the invention.

FIG. 3 is a back view of a container of the mobile synchronous condenser system with a door open in accordance with an embodiment of the invention.

FIG. 4 is an internal view of the container of the mobile synchronous condenser system in accordance with an embodiment of the invention.

FIG. 5 is a diagram of a covered control panel of the mobile synchronous condenser system in accordance with an embodiment of the invention.

FIG. 6 is a diagram of an external control panel of the mobile synchronous condenser system in accordance with an embodiment of the invention.

FIG. 7 is a bottom perspective view of the mobile synchronous condenser system in accordance with an embodiment of the invention.

FIG. 8 is a schematic of the electrical components of the mobile synchronous condenser system in accordance with an embodiment of the invention.

FIG. 9 is a process flow diagram of a method in accordance with an embodiment of the invention.

Throughout the description, similar reference numbers may be used to identify similar elements.

### DETAILED DESCRIPTION

It will be readily understood that the components of the embodiments as generally described herein and illustrated in the appended Figs. could be arranged and designed in a wide variety of different configurations. Thus, the following more detailed description of various embodiments, as represented in the Figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the embodiments is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment”, “an embodiment”, or similar language means that a particular feature, structure, or characteristic described in connection with the indicated embodiment is included in at least one embodiment of the present invention. Thus, the phrases “in one embodiment”, “in an embodiment”, and similar language throughout this specification may, but do not necessarily, all refer to the same embodiment.

As described above, traditional synchronous condensers need to be installed at a designated facility, such as a substation, which requires interconnections of numerous components, which may include heating and cooling components and control system components. A synchronous condenser and the supporting components are usually installed in a dedicated building, which provides an operating environment for the synchronous condenser. The heating and cooling components ensure that the operating environment for the synchronous condenser is maintained at a proper temperature.

Thus, traditional synchronous condensers are designed to be stationary machineries that are installed at designated locations. Once installed, the synchronous condensers cannot be easily moved to a different location. However, in some scenarios, a synchronous condenser that can be moved to a new or different location and be easily setup at that location may be preferred.

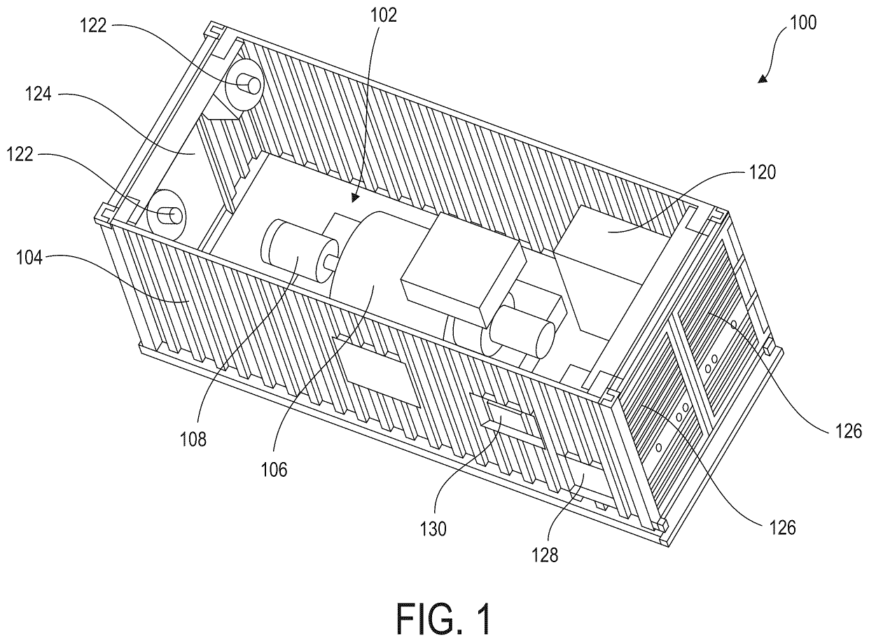

Turning now to FIG. 1, a mobile synchronous condenser system 100 in accordance with an embodiment of the invention is shown. As described in detail below, the mobile synchronous condenser system 100 is a self-contained synchronous condenser machine with a synchronous condenser unit 102, which includes various supporting components for the synchronous condenser unit 102. These supporting components are preassembled and/or preinstalled so that the mobile synchronous condenser system 100 can be easily connected to an electrical power network, e.g., a regional electricity grid, at a desired location, such as a substation, without having to install the synchronous condenser unit 102 with the various supporting components at the desired location, which may involve attaching at least some of the components to a physical structure, such as a dedicated building, and connecting the various components together to ensure that the synchronous condenser unit 102 is functioning properly.

As shown in FIG. 1, the mobile synchronous condenser system 100 includes the synchronous condenser unit 102, which is positioned within a container 104 that provides an operating environment for the synchronous condenser unit 102. The container 104 may be a fully enclosed structure, and can be made of any material, such as metal. In an embodiment, the container 104 is a rectangular container. As an example, the container 104 may be a twenty (20) foot container with a height of 7.9 feet or 2.39 meters, a width of 7.8 feet or 2.35 meters and a length of 19.4 feet or 5.9 meters. In a particular implementation, the container 104 can be made of a standard twenty (20) foot shipping container. Since shipping containers are standardized containers, the use of a standard shipping container for the mobile synchronous condenser system 100 allows the entire system to be easily transported to a desired location using common transportation means, such as container ships, freight trains and semi-trucks.

The synchronous condenser unit 102 is mounted onto the container 104. In an embodiment, the synchronous condenser unit 102 is mounted onto the floor of the container 104 within the internal space of the container using any appropriate means, such as bolts. The synchronous condenser unit 102 includes a synchronous condenser 106 and a pony motor 108. The synchronous condenser 106 includes an electric motor that is designed to run without a mechanical load. The synchronous condenser 106 can include any sized electric motor, such as a one (1) megawatt electric motor. The pony motor 108 is a starter motor for the synchronous condenser 106 to start rotating the synchronous condenser. Thus, the pony motor 108 is a significantly smaller motor when compared to the synchronous condenser 106. In a particular implementation, the weight of the synchronous condenser unit 102 may be 12,000 pounds (lbs) or more.

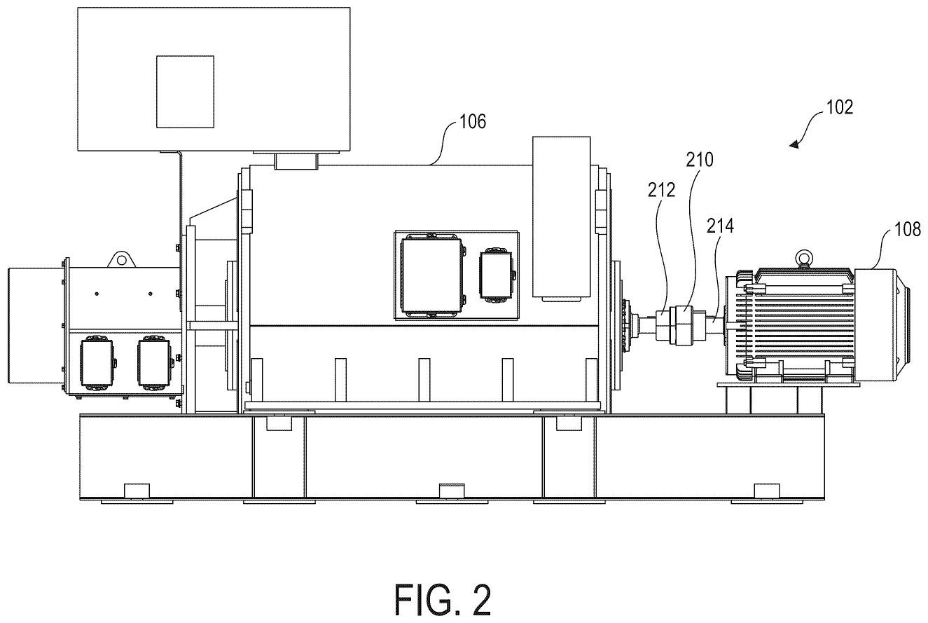

Turning now to FIG. 2, the synchronous condenser unit 102 in accordance with an embodiment of the invention is illustrated. As shown in FIG. 2, the synchronous condenser 106 is connected to the pony motor 108 via a shaft connector 210, which connects a shaft 212 of the synchronous condenser 106 and a shaft 214 of the pony motor 108. In this embodiment, the synchronous condenser unit 102 may include controls and other components commonly found in a synchronous condenser unit.

Turning back to FIG. 1, the synchronous condenser unit 102 is connected to electrical components within at least one electrical box 120. In an embodiment, the electrical box 120 may include a heater (not shown), which can heat an operating environment of the synchronous condenser unit 102, i.e., the space within the container 104 where the synchronous condenser unit 102 is placed. The electrical box 120 may also include a battery that can be used to run various electrical components of the mobile synchronous condenser system 100. The container 104 further includes ventilation cooling fans 122 to vent the heat generated by the synchronous condenser unit 102. In the illustrated embodiment, there are two (2) high-powered ventilation cooling fans 122. However, in other embodiments, the container 104 may include one or more than two (2) ventilation cooling fans 122. In addition, in the illustrated embodiment, the ventilation cooling fans 122 are mounted near the top at the end of the container 104, where there is a door 124 of the container 104, which allows an operator to service the synchronous condenser unit 102 and other components inside the container 104. However, in other embodiments, the ventilation cooling fans 122 may be mounted anywhere on the container 104. The other end of the container 104, which is on the opposite side of the door 124, includes air inlet louver vents 126 to allow ambient air to circulate into the container 104. Thus, the heater and the ventilation cooling fans 122 are parts of a temperature control system for the container 104 so that the temperature inside of the container, i.e., the operating environment for the synchronous condenser unit 102, can be maintained at a proper temperature.

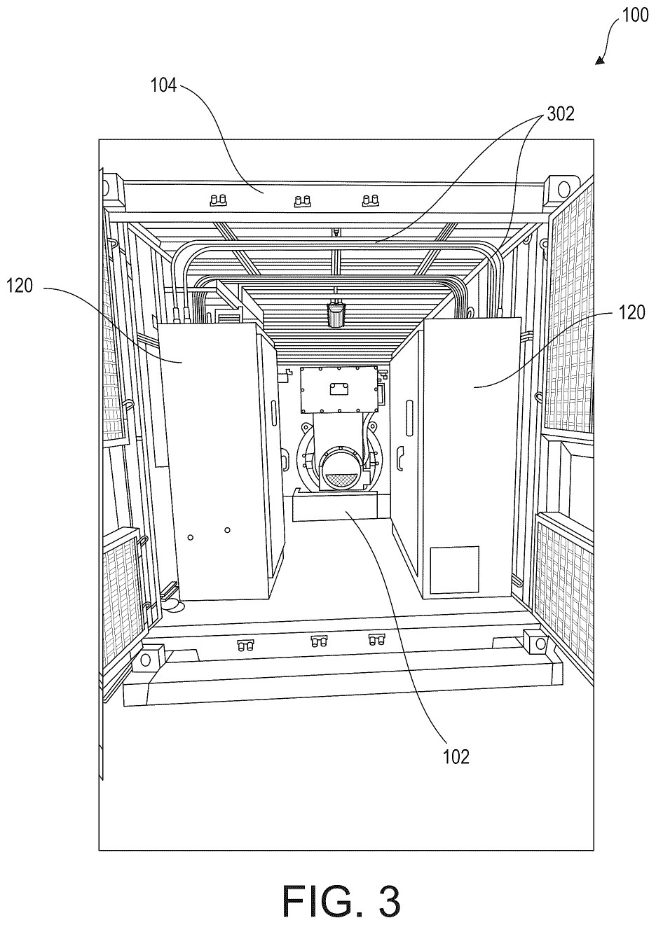

In the illustrated embodiment, at least some of the electrical components in the electrical box 120 are connected to a power panel 128, e.g., a cam-lock panel, using internal cables, which may run across the top or ceiling of the container 104. In embodiments where there are multiple electrical boxes 120, electrical wires in metal tubes may be used to connect between some of the components of the electrical boxes 120, as illustrated in FIG. 3, which is a back view of the container 104 with the door 124 open in accordance with an embodiment of the invention. As shown in FIG. 3, metal tubes 302 containing electrical wires are used to electrically connect between components of two electrical boxes 120.

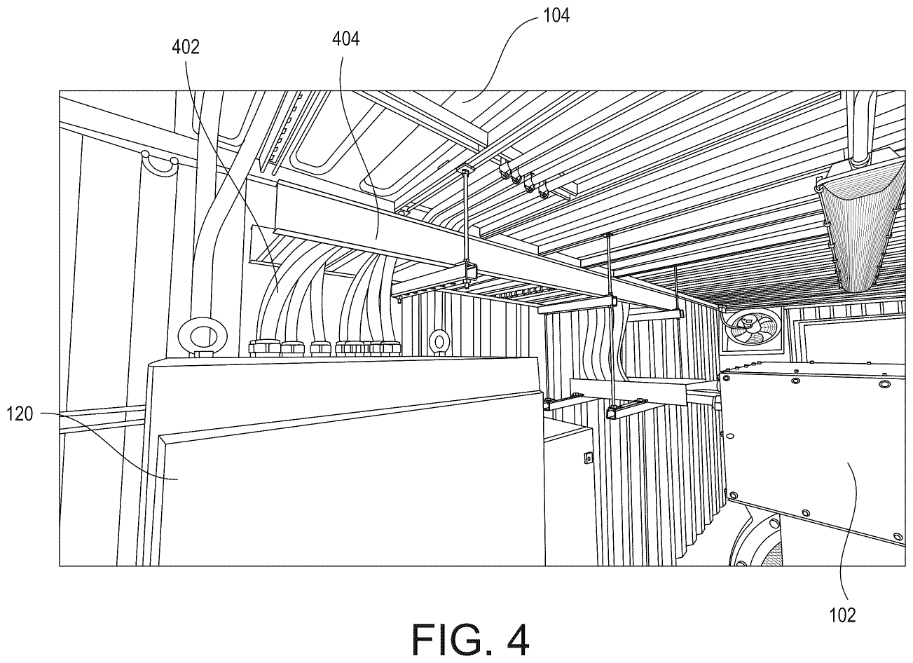

The power panel 128, e.g., a cam-lock panel, which can be mounted on an exterior surface of the container 104, includes one or more connectors for exterior electrical cable connections. As an example, at least one of the connectors in the power panel 128 may be used to connect to an electrical power network, e.g., a regional electric or power grid, so that the mobile synchronous condenser system 100 can be used for, among others, protection and stability of the electrical power network. The internal cables between some of the electrical components in the electrical box 120 and the power panel 128 may extend across the ceiling of the container 104 using a channel type structure that is designed to carry heavy cables, as illustrated in FIG. 4, which is an internal view of the container 104 in accordance with an embodiment of the invention. As shown in FIG. 4, internal cables 402 are secured using a channel type structure 404, which is secured to the ceiling of the container 104 to connect some of the electrical components in the electrical box 120 to the power panel 128 (not shown in FIG. 4).

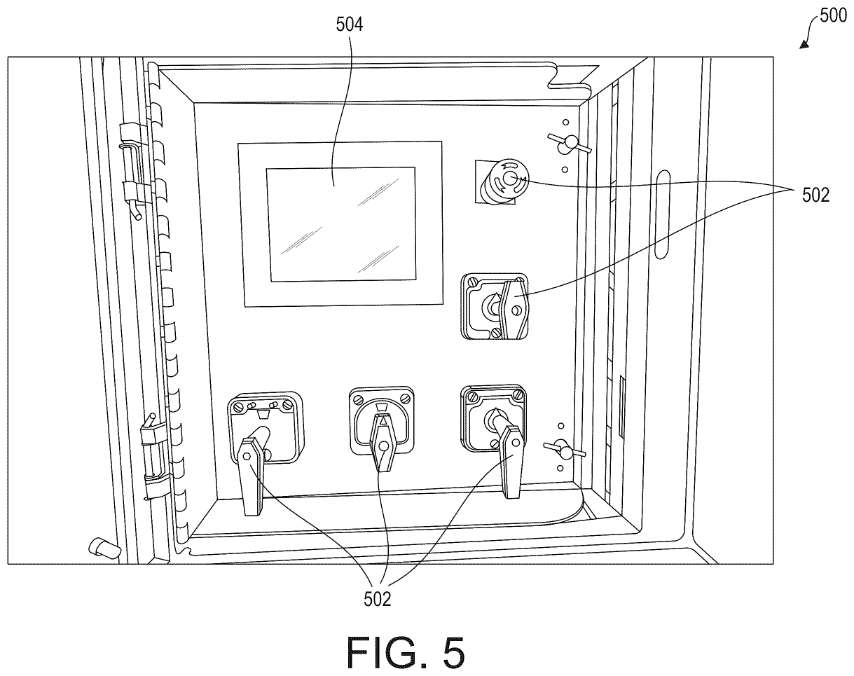

In an embodiment, as illustrated in FIG. 5, the mobile synchronous condenser system 100 may include a covered control panel 500, which may be placed behind one of the air inlet louver vents 126. The control panel 500 may include various controls 502 and a display 504, which may a touchscreen display. As an example, as shown in FIG. 5, the controls 502 may include an emergency cutoff switch, a motor start switch, a breaker control switch, a lock-out relay switch and a power factor (PF)/volt-amperes reactive (VAR) control switch.

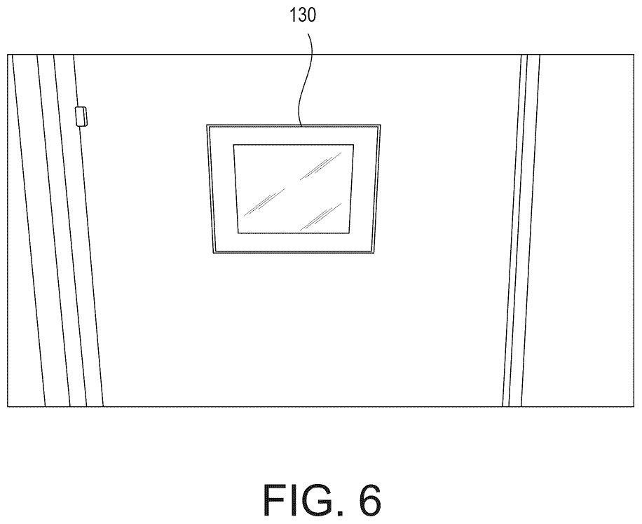

Turning back to FIG. 1, in the illustrated embodiment, the mobile synchronous condenser system 100 further includes an external control panel 130 that is mounted on the side of the container 104. The external control panel 130 is electrically connected to the synchronous condenser unit 102 to control its operation, e.g., the operation of the synchronous condenser 106 and the pony motor 108. Thus, the external control panel 130 allows an operator to easily turn on or shutoff the synchronous condenser unit 102 without having to be inside of the container 104 or using the covered control panel 500. In an embodiment, as illustrated in FIG. 6, the external control panel 130 is a display, which may be a touchscreen display.

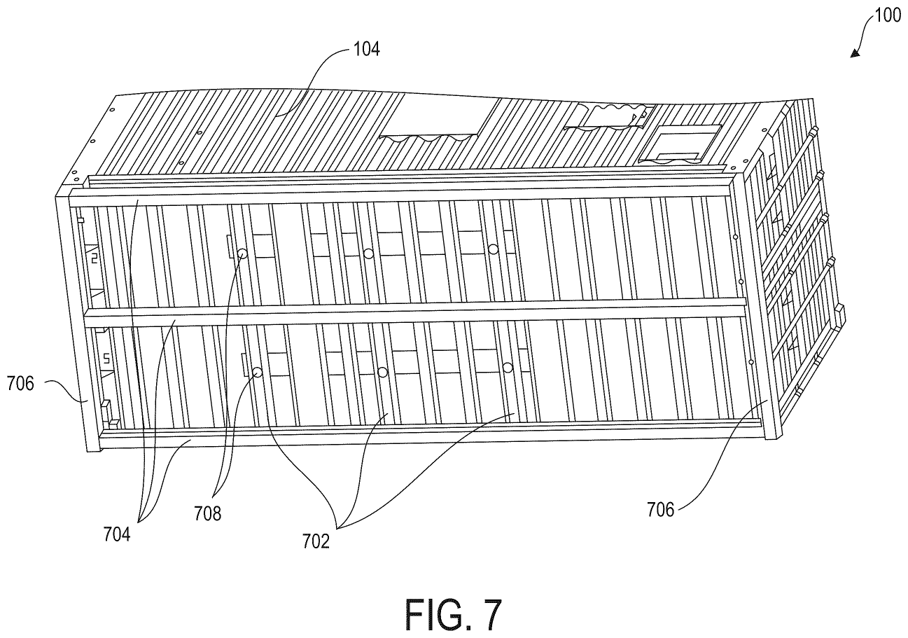

In some embodiments, the bottom of the container 104 may be reinforced in order to support the synchronous condenser unit 102. FIG. 7 is a bottom perspective view of the container 104 in accordance with an embodiment of the invention. As shown in FIG. 7, the container 104 is built with a re-enforced floor with heavy gauge steel tubes 702, 704 and 706 mounted onto the bottom of the container. In the illustrated embodiment, the container floor includes three (3) steel tubes 702, which are separated by three (3) feet apart from each other. However, in other embodiments, the container floor may include fewer or more steel tubes 702, which may be separated by other distances. The size of the steel tubes 702 can vary. As an example, each steel tube 702 may be four (4) inches wide and four (4) inches high.

In the illustrated embodiment, each of the steel tubes 702 has two (2) bolt pockets 708 for 1.5 inch×6 inch grade-9 bolts, which are three (3) feet apart. The bolt pockets are used to mount the synchronous condenser unit 102 onto the container floor using bolts. Thus, the synchronous condenser unit 102 is mounted onto the bottom of the container 104 using six (6) substantially reinforced mounting bolts, e.g., six (6) grade-9 steel bolts. However, in other embodiments, each of the steel tubes 702 may have any number of bolt pockets for any size bolts, which separated by different distances, to mount the synchronous condenser unit 102 onto the container floor.

The steel tubes 704 are mounted onto the bottom of the container 104 along the length of the container. In the illustrated embodiment, there are three (3) steel tubes 704. Two (2) of the steel tubes 704 are mounted near the side edges of the container floor. The remaining steel tube is mounted in the middle of the container floor. Similar to the steel tubes 702, each steel tube 704 may be four (4) inches wide and four (4) inches high.

The steel tubes 706 are mounted onto the bottom of the container 104 along the width of the container. In the illustrated embodiment, there are two (2) steel tubes 706 near the front and back edges of the container floor. Similar to the steel tubes 702, each steel tube 706 may be four (4) inches wide and four (4) inches high. The steel tubes 706 may be open to allow insertion of thick metal pieces, which themselves can be bolted to the ground for stability of the container 104 while the sync-condenser is in operation.

Although the tubes 702, 704 and 706 have been described as being steel tubes, these tubes can be made of any metal or other suitable material. In some alternative embodiments, the tubes 702, 704 and 706 may be replaced with solid bars or other reinforcement structures for the floor of the container 104.

The base frame of the mobile synchronous condenser system 100, i.e., the container 104 by itself, weighs approximately 8,000 lbs. In an embodiment, some of the steel tubes 702, 704 and 706 are designed to accept large forklift forks, which may have a lifting capacity of 40,000 lbs. As an example, the tubes 704 at the side edges of the container 104 may include openings to allow a forklift vehicle to insert the forklift to move the entire container 104 with the synchronous condenser unit 102 as needed.

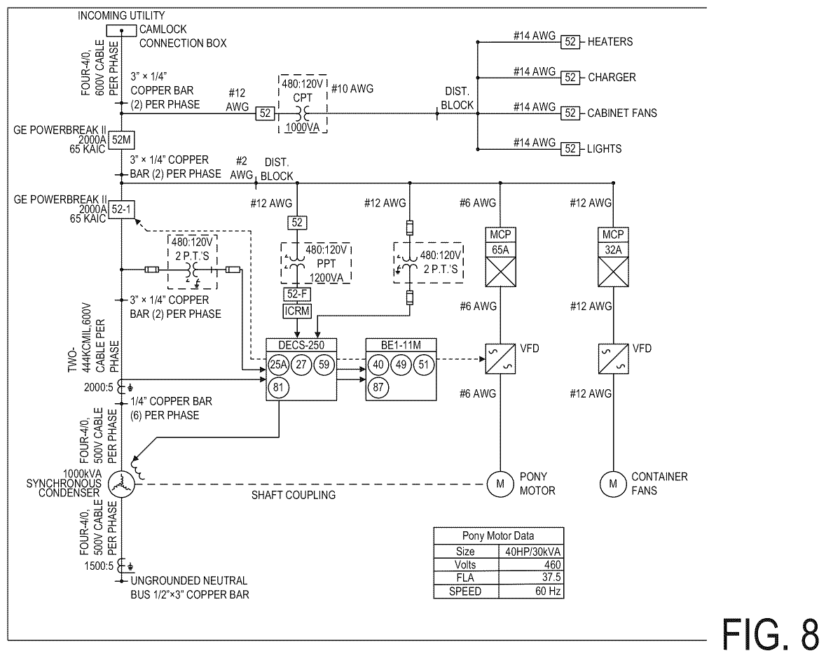

Turning now to FIG. 8, a schematic of the electrical components of the mobile synchronous condenser system 100. The schematic shows various electrical devices of the mobile synchronous condenser system 100, such as heaters, a charger (battery), cabinet fans and lights, which are connected to receive input electrical power “incoming utility” through a transformer. The schematic also shows the container fans, the pony motor and the synchronous condenser connected to the input electrical power through fuses, transformers, main circuit protections (MCPs), variable frequency drives (VFDs), circuit breakers and/or control circuitries.

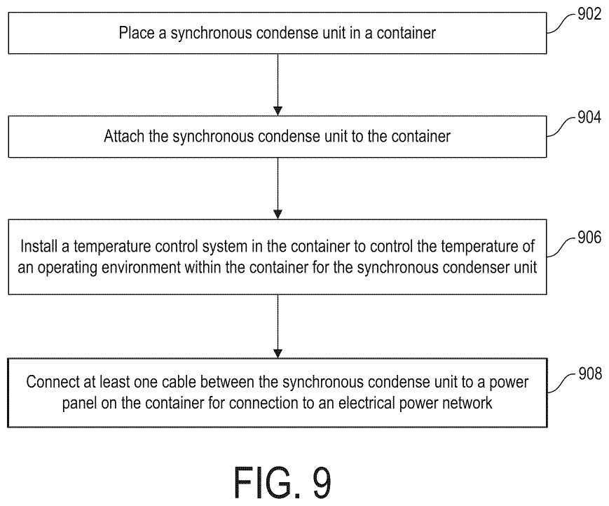

A method in accordance with an embodiment of the invention is described with reference to a process flow diagram of FIG. 9. At block 902, a synchronous condense unit is placed in a container. At block 904, the synchronous condense unit is attached to (e.g., mounted onto) the container. At block 906, a temperature control system is installed in the container to control the temperature of an operating environment within the container for the synchronous condenser unit. At block 908, a cable is connected between the synchronous condense unit to a power panel on the container for connection to an electric power network.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A mobile synchronous condenser system comprising:
a container;
a synchronous condenser unit attached to the container such that the synchronous condenser unit is positioned within the container; and
a power panel attached to the container, wherein the synchronous condenser unit is electrically connected to the power panel via at least one cable, wherein the power panel includes at least one connector to connect to an electrical power network using at least one external cable.

2. The mobile synchronous condenser system of claim 1, further comprising a temperature control system attached to the container to control a temperature of an operating environment within the container for the synchronous condenser unit.

3. The mobile synchronous condenser system of claim 2, wherein the temperature control system includes at least one ventilation fan attached to the container.

4. The mobile synchronous condenser system of claim 2, wherein the temperature control system includes a heater positioned in the container.

5. The mobile synchronous condenser system of claim 1, wherein the synchronous condenser unit includes a synchronous condenser and a motor configured to start the synchronous condenser.

6. The mobile synchronous condenser system of claim 1, wherein the power panel includes a cam-lock panel attached to an exterior surface of the container.

7. The mobile synchronous condenser system of claim 1, further comprising a control panel attached to an exterior surface of the container.

8. The mobile synchronous condenser system of claim 1, further comprising a channel type structure attached to a ceiling of the container to secure cables from electrical components in the container to the power panel.

9. The mobile synchronous condenser system of claim 1, wherein the container includes at least one air inlet louver vent to allow ambient air to flow into the container.

10. A mobile synchronous condenser system comprising:
a shipping container;
a synchronous condenser unit attached to the shipping container such that the synchronous condenser unit is positioned within the shipping container;
a power panel attached to the shipping container, wherein the synchronous condenser unit is electrically connected to the power panel via at least one cable, wherein the power panel includes at least one connector to connect to an electrical power network using at least one external cable; and
a temperature control system attached to the shipping container to control a temperature of an operating environment within the shipping container for the synchronous condenser unit.

11. The mobile synchronous condenser system of claim 10, wherein the synchronous condenser unit includes a synchronous condenser and a motor configured to start the synchronous condenser.

12. The mobile synchronous condenser system of claim 10, wherein the temperature control system includes at least one ventilation fan attached to the shipping container.

13. The mobile synchronous condenser system of claim 10, wherein the temperature control system includes a heater positioned in the shipping container.

14. The mobile synchronous condenser system of claim 10, wherein the power panel includes a cam-lock panel attached to an exterior surface of the shipping container.

15. The mobile synchronous condenser system of claim 10, further comprising a control panel attached to an exterior surface of the shipping container.

16. The mobile synchronous condenser system of claim 10, further comprising a channel type structure attached to a ceiling of the shipping container to secure cables from electrical components in the shipping container to the power panel.

17. The mobile synchronous condenser system of claim 10, wherein the shipping container includes at least one air inlet louver vent to allow ambient air to flow into the shipping container.

18. A method comprising:
placing a synchronous condense unit in a container;
attaching the synchronous condense unit to the container;
installing a temperature control system in the container to control the temperature of an operating environment within the container for the synchronous condenser unit; and
connecting at least one cable between the synchronous condense unit to a power panel on the container for connection to an electric power network.

19. The method of claim 18, wherein the synchronous condenser unit includes a synchronous condenser and a motor configured to start the synchronous condenser.

20. The method of claim 18, wherein the temperature control system includes at least one ventilation fan attached to the container or a heater positioned in the container.
